(19) United States
(12) Patent Application Publication
(10) Pub. No.: US 2013/0027856 A1
(43) Pub. Date: Jan. 31, 2013

(54) ELECTRONIC APPARATUS WITH ROTATION FUNCTION

(71) Applicants: Tzu-Wei TAI, Taipei (TW); Cheng-Wei Chen, Taipei (TW); Szu-Tang Chiu, Taipei (TW); Yu-Chao Su, Taipei (TW); Yi-Rui Lin, Taipei (TW); Shu-Chun Hsiao, Taipei (TW)

(72) Inventors: Tzu-Wei TAI, Taipei (TW); Cheng-Wei Chen, Taipei (TW); Szu-Tang Chiu, Taipei (TW); Yu-Chao Su, Taipei (TW); Yi-Rui Lin, Taipei (TW); Shu-Chun Hsiao, Taipei (TW)

(21) Appl. No.: 13/558,690

(22) Filed: Jul. 26, 2012

(30) Foreign Application Priority Data
Jul. 27, 2011 (TW) 100126685

(51) Int. Cl. H05K 7/00

(52) U.S. Cl. 361/679.01

(57) ABSTRACT

An electronic apparatus with rotation function includes a loading side, a stationary portion and a rotation portion. The stationary portion is disposed at the loading side. The rotation portion is configured for connecting with a functional apparatus. The rotation portion is connected with the stationary portion in an unfixed way. The functional apparatus rotates relative to the stationary portion by the rotation portion.

### CROSS REFERENCE TO RELATED APPLICATIONS

This Non-provisional application claims priority under 35 U.S.C. §119(a) on Patent Application No(s). 100126685 filed in Taiwan, Republic of China on Jul. 27, 2011, the entire contents of which are hereby incorporated by reference.

### BACKGROUND OF THE INVENTION

1. Field of Invention

The disclosure relates to an electronic apparatus and, in particular, to an electronic apparatus that allows a functional apparatus to install thereon.

2. Related Art

“Digital Home” is a concept that has become the major and future trend in the recent years. For example, many people prefer to setup a computer in their living rooms for accessing internet anywhere at home. At the mean time, the small sized host, such as nettop computers, was commercialized and very popular. Some of the small-sized nettops may be installed on a frame, and then fasten the frame on the wall or on any electronic devices such as the television or the screen for more space saving.

However, if the host is fastened on the back of the screen, the connection port (I/O port) on the host is not easy to be accessed wherever the I/O ports locate. Currently, the I/O ports of the host are located at the left or right side of the host, and users need to connect the host across the entire screen for a long distance. If the I/O ports of the host are positioned upward, it is still inconvenient for the users since the operation buttons are at the side opposite to the I/O port which is faced downward. Furthermore, if the I/O ports of the host are positioned downward, users are difficult to insert the connector correctly due to the vision limitation as well.

### SUMMARY OF THE INVENTION

The disclosure provides an electronic apparatus for users to install a small sized host thereon, insert the connectors and operate it easily.

An electronic apparatus with rotation function is disclosed. The electronic apparatus comprises a loading side, a stationary portion and a rotation portion. The stationary portion is disposed at the loading side, and the rotation portion is configured for connecting with a functional apparatus. The functional apparatus rotates relative to the stationary portion by the rotation portion.

As mentioned above, the electronic apparatus of this disclosure includes a stationary portion and a rotation portion, which are disposed on the loading side thereof, and the rotation portion rotates with respect to the stationary portion and connects to a functional apparatus (e.g. a small sized host). Thus, the functional apparatus can be rotated with respect to the stationary portion by the rotation portion, so that the functional apparatus can be rotated to a proper position for the user to conveniently insert the connecters or operate the operation interface. Besides, the stationary portion can be integrally formed on the electronic apparatus, so the conventional frame is not needed anymore. Therefore, the user does not have to install the frame, and can avoid the inconvenient problems of inserting the connecters. Accordingly, the usage performance can be sufficiently enhanced.

These and other features, aspects and advantages of the disclosure will become better understood with regard to the following description, appended claims, and accompanying drawings.

### BRIEF DESCRIPTION OF THE DRAWINGS

FIG. 1 is a schematic diagram of an electronic apparatus with rotation function according to a first embodiment of the disclosure;

FIGS. 2A and 2B are exploded views showing the functional apparatus and the stationary portion and rotation portion of the electronic apparatus according to a first embodiment of the disclosure;

FIGS. 3A and 3B are assembled diagrams of the functional apparatus and the stationary portion and rotation portion of the electronic apparatus of FIG. 1;

FIGS. 4A and 4B are exploded views showing the functional apparatus and the stationary portion and rotation portion of the electronic apparatus according to a second embodiment of the disclosure;

FIGS. 5A and 5B are assembled diagrams of the functional apparatus and the stationary portion and rotation portion of the electronic apparatus according to a second embodiment of the disclosure;

FIGS. 6 and 7A are schematic diagrams of a stationary portion and a rotation portion of an electronic apparatus with rotation function according a third embodiment of the disclosure in different view;

FIG. 7B is a schematic diagram of the functional apparatus connecting with the rotation portion according the third embodiment of the disclosure;

FIG. 8 is an assembled diagram of a stationary portion and a rotation portion of an electronic apparatus with rotation function according to a fourth embodiment of the disclosure;

FIG. 9 is a sectional view of the stationary portion and rotation portion of the fourth embodiment; and

FIG. 10 is an assembled diagram of a stationary portion and a rotation portion of an electronic apparatus with rotation function according to a fifth embodiment of the disclosure.

### DETAILED DESCRIPTION OF THE INVENTION

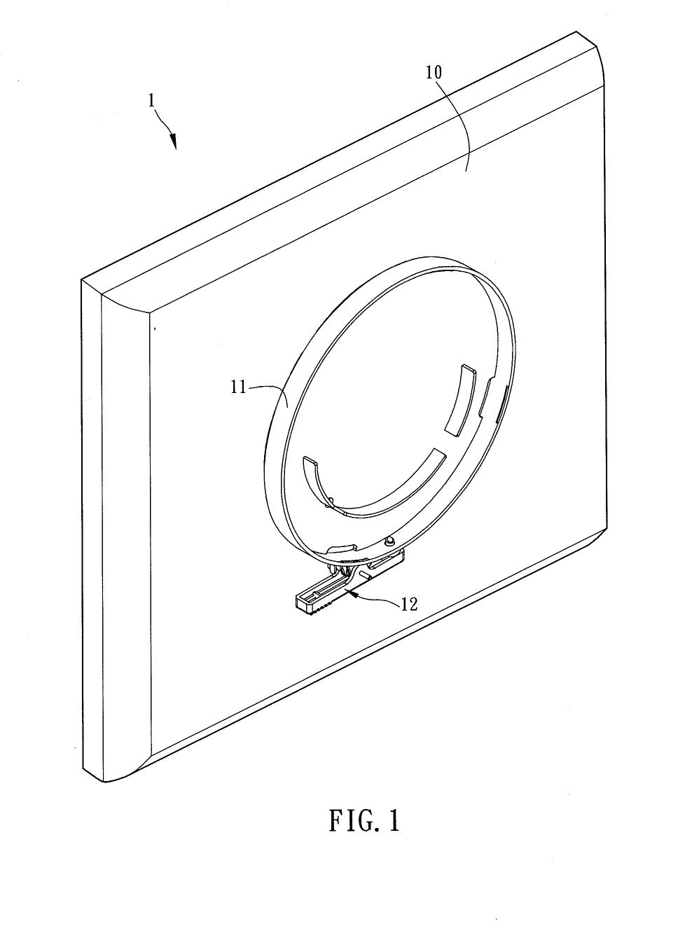

FIG. 1 is a schematic diagram of an electronic apparatus 1 with rotation function according to a first embodiment of the disclosure. The electronic apparatus 1 can be a television, a display, a computer, or any other electronic apparatus. In the embodiment, a television is taken as an example.

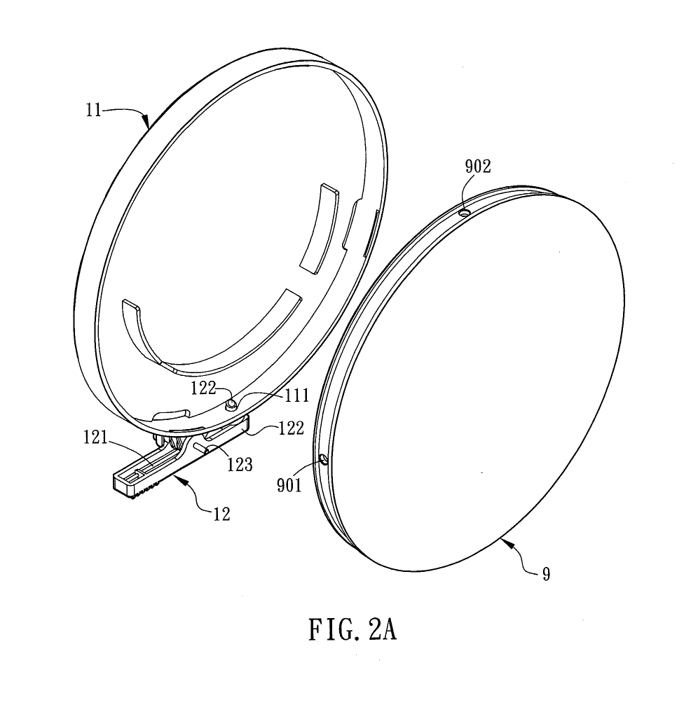

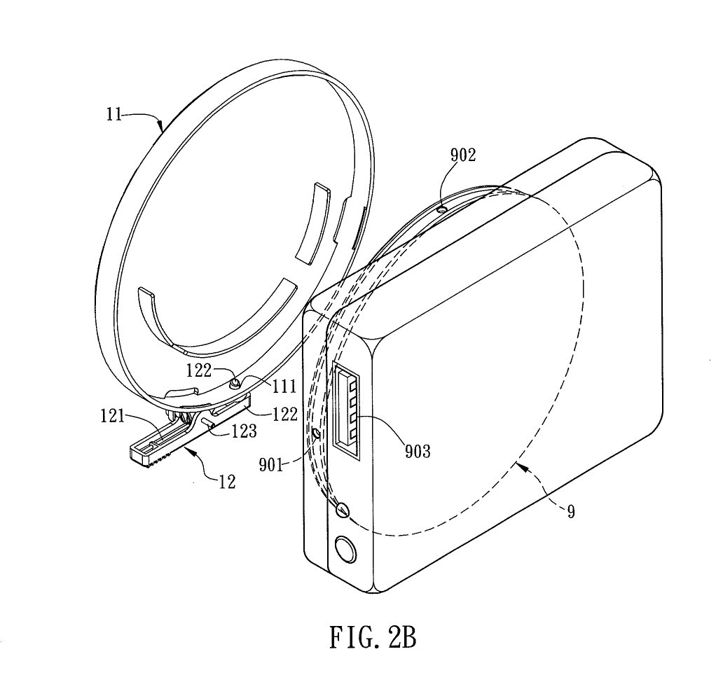

The electronic apparatus 1 comprises a loading side 10, a stationary portion 11 and a rotation portion 12. The stationary portion 11 is disposed at the loading side 10. The rotation portion 12 is connected with the stationary portion 11 and is configured for connecting with a functional apparatus 9 (see FIG. 2). The functional apparatus 9 rotates relative to the stationary portion 11 by the rotation portion 12.

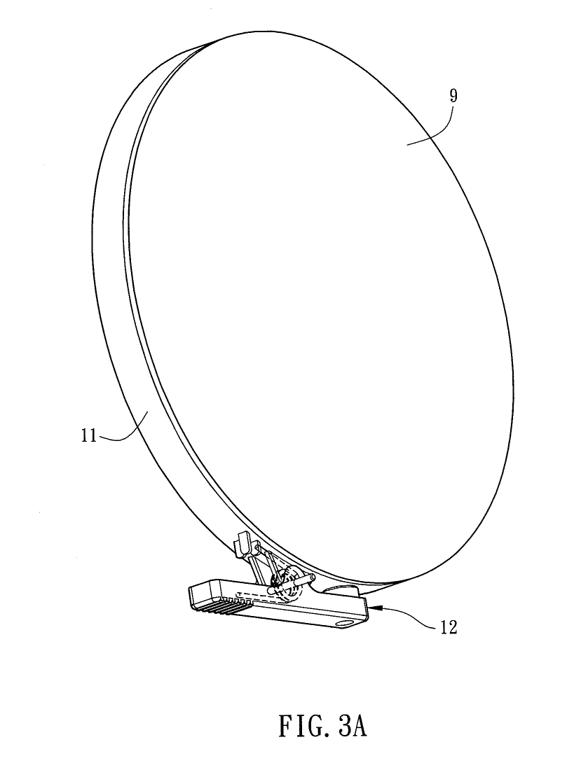

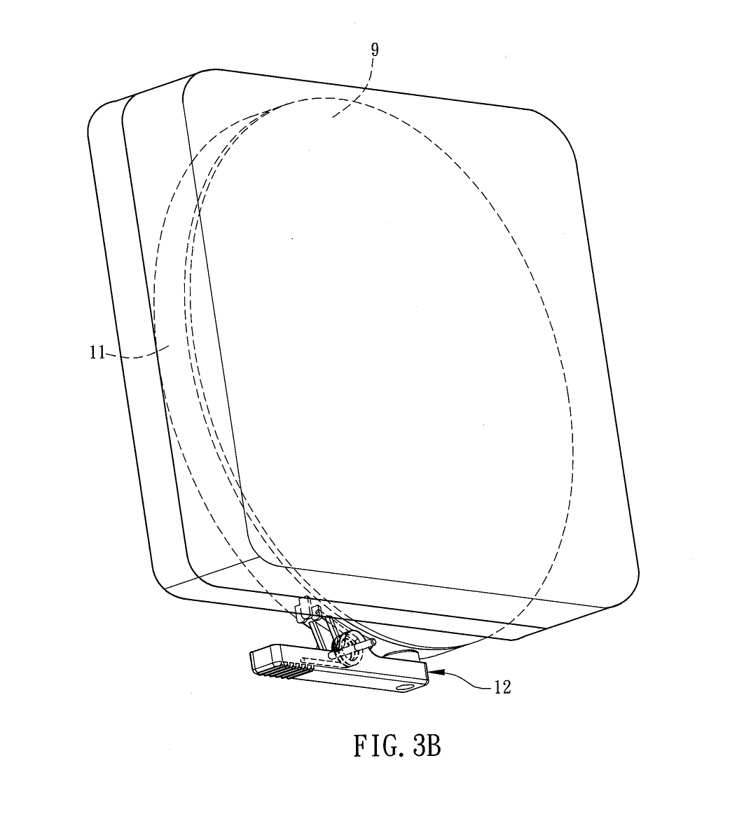

FIGS. 2A and 2B are exploded views showing the functional apparatus 9 and the stationary portion 11 and the rotation portion 12 of the electronic apparatus 1, and FIGS. 3A and 3B are assembled diagrams of the functional apparatus 9, the stationary portion 11 and rotation portion 12. To be noted, in FIGS. 2A and 3A, the functional apparatus 9 is omitted since it may block other parts to be illustrated.

Referring to FIGS. 2A to 3B, the stationary portion 11 is fixed on the loading side 10 of the electronic apparatus 1 by hooking, telescoping, locking or integrally forming. The shape of the stationary portion 11 may be a hollow circle, a solid circle, a ring, or their combinations. In this embodiment, the stationary portion 11 is disposed on the loading side 10 by integrally forming, and the shape of the stationary portion 11 is a hollow circle.

The rotation portion 12 is connected to the stationary portion 11 in an unfixed way, such that the rotational portion 12 can rotate with respect to the stationary portion 11. In this embodiment, the rotation portion 12 includes a spring 121, a connecting portion 122 and a bolt 123. The spring 121 is disposed around the connecting portion 122 for providing a restoring force, and the bolt 123 is disposed passing through the connecting portion 122 and the stationary portion 11. In this embodiment, the spring 121 is a spring, and the connecting portion 122 is a protrusion base, but not limited to in the disclosure.

When the rotation portion 12 and the spring 121 are located at the first position (the spring 121 is in non-compressed state), the connecting portion 122 passes through a fixing hole 111 of the stationary portion 11 and a location hole 901 of the functional apparatus 9 for connecting to the stationary portion 11 and the functional apparatus 9. Thus, the functional apparatus 9 can be restricted at a specific position and cannot be rotated.

When the rotation portion 12 and the spring 121 are located at the second position (the spring 121 is in compressed state), the connecting portion 122 is separated from the location hole 901 of the functional apparatus 9, so that the functional apparatus 9 can be rotated with respect to the stationary portion 11. After the functional apparatus 9 is rotated to another specific position (e.g. the fixing hole 111 is aligned with the location hole 902), the rotation portion 12 and the spring 121 are turned to the first position, so that the connecting portion 122 passes through the fixing hole 111 of the stationary portion 11 and the location hole 901 of the functional apparatus 9 for connecting to the stationary portion 11 and the functional apparatus 9. Thus, the functional apparatus 9 can not be rotated.

To be noted, the number and positions of the location holes may be varied depending on the actual situations, and are not limited to this example. Consequently, the functional apparatus 9 can be rotated to the proper position and fixed. For example, the functional apparatus 9 may be rotated to the position allowing the connecting port to face upwardly, so that the user can conveniently insert the connectors; otherwise, it may be rotated to the position allowing the operation interface of the functional apparatus 9 to face upwardly, so that the user can easily operate the operation interface.

In particular, the performance of the functional apparatus 9 can be increased after rotating to a specific position. For example, the functional apparatus 9 can be an electronic apparatus with connecting port (e.g. I/O port), which includes a computer host, an optical disc drive, a server, a printer, a router, a wireless access point, or a processor. The outer shape of the functional apparatus 9 is coordinated with the inner shape of the stationary portion 11, which is preferably circular, so that the functional apparatus 9 can easily rotate with respect to the stationary portion 11. As shown in FIG. 2B, the functional apparatus 9 includes a plurality of connecting ports 903, which can be any applicable connecters such as HDMI, USB, or the likes. Accordingly, the functional apparatus 9 can be rotated to the position that allows the user to easily insert the connecter into the connecting port 903.

Alternatively, the outer shape of the functional apparatus 9 may be a sector, a ring, or an arc, which allows the functional apparatus 9 to rotate with respect to the stationary portion 11. Besides, an auxiliary structure for rotation, such as guiding rails, can be configured at the inner periphery of the stationary portion 11 and/or the outer periphery of the functional apparatus 9.

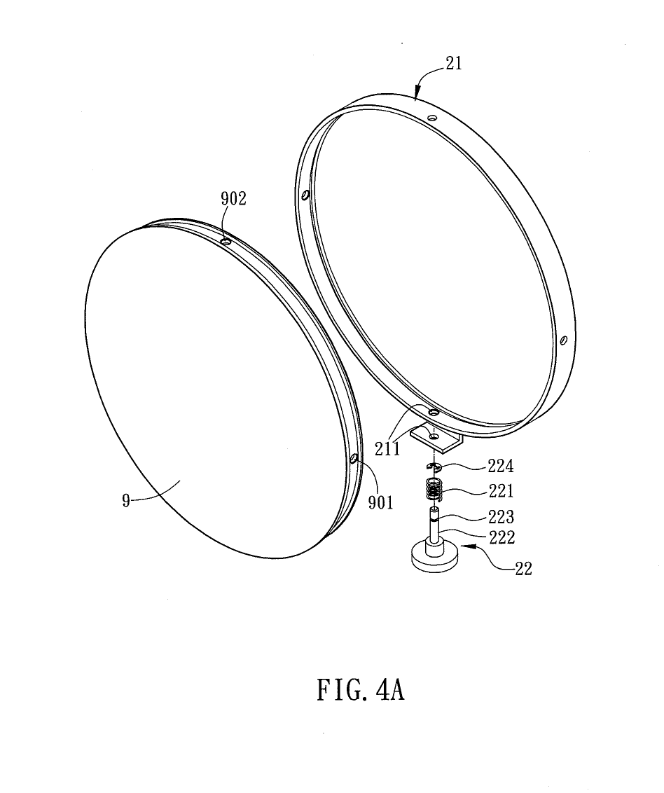

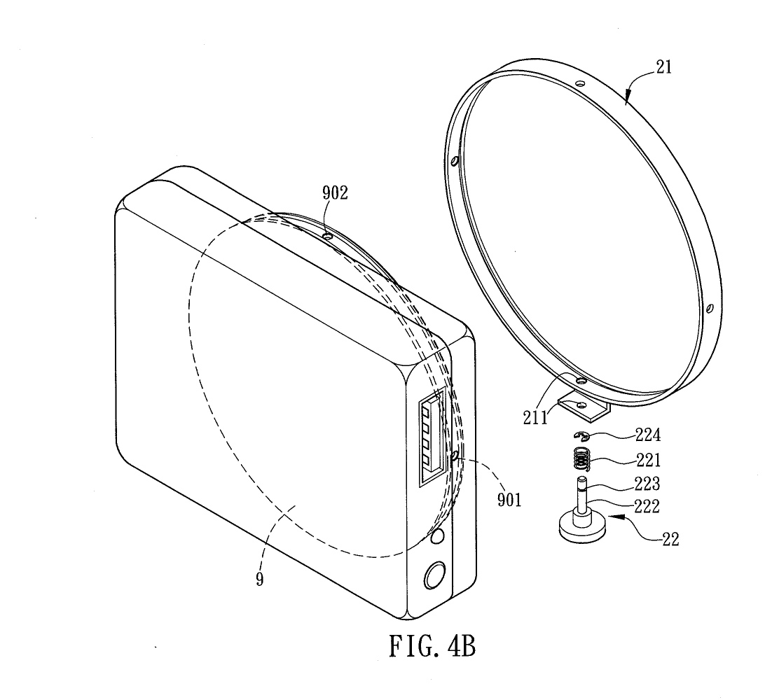

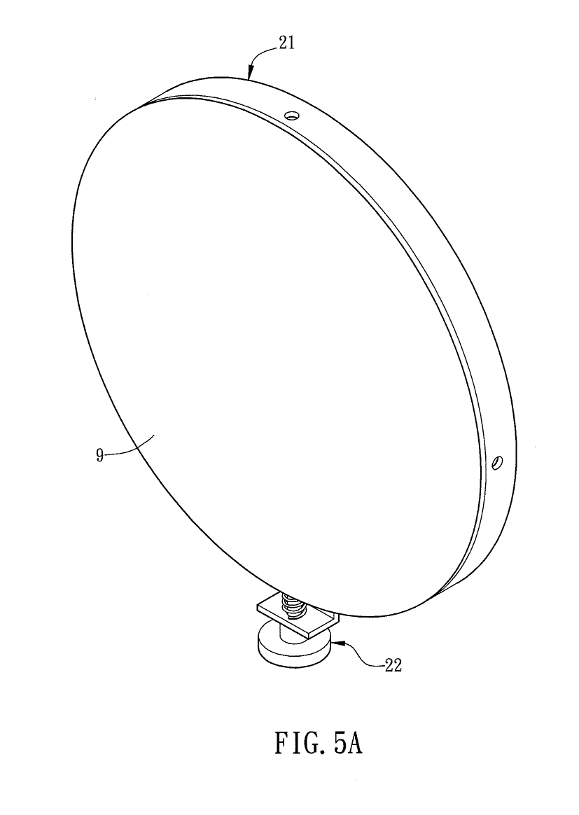

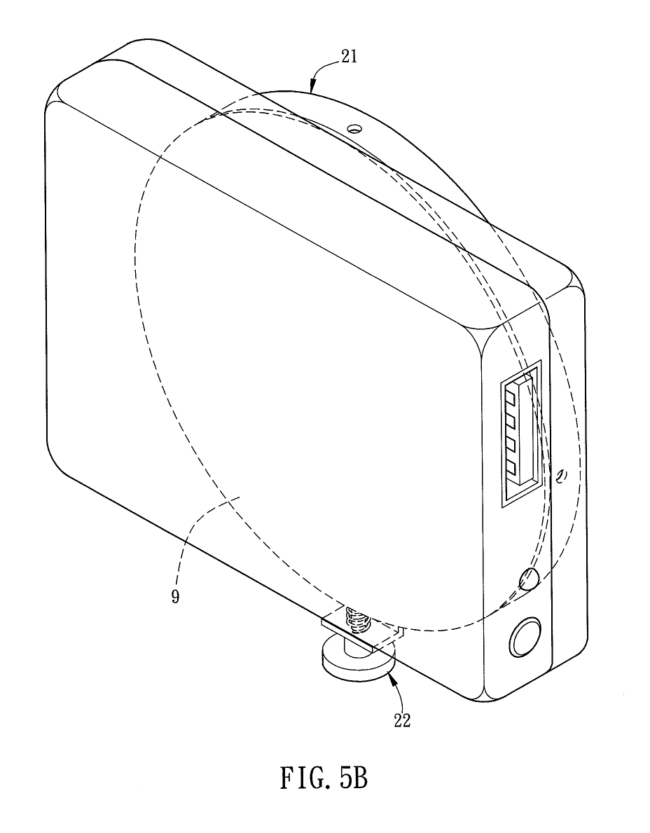

FIGS. 4A and 4B are exploded views showing the functional apparatus 9 and a stationary portion 21 and a rotation portion 22 of an electronic apparatus according to a second embodiment of the disclosure, and FIGS. 5A and 5B are assembled diagrams of the stationary portion 21, the rotation portion 22, and the functional apparatus 9. To be noted, in FIGS. 4A and 5A, the functional apparatus 9 is omitted since it may block other parts to be illustrated.

With reference to FIGS. 4A to 5B, in the second embodiment, the connecting portion 222 of the rotation portion 22 is a protrusion rod with a recess 223, and a fixing ring 224 is disposed in the recess 223 for limiting the spring 221.

When the rotation portion 22 and the spring 221 are located at the first position (the spring 221 is in non-compressed state), the connecting portion 222 passes through a fixing hole 211 of the stationary portion 21 and a location hole 901 of the functional apparatus 9 for connecting to the stationary portion 21 and the functional apparatus 9. Thus, the functional apparatus 9 can be fixed at a specific position and can not be rotated.

When the rotation portion 22 and the spring 221 are located at the second position (the connecting portion 222 is pulled downwardly and the spring 221 is in compressed state), the connecting portion 222 is separated from the location hole 901 of the functional apparatus 9, so that the functional apparatus 9 can be rotated with respect to the stationary portion 21. After the functional apparatus 9 is rotated to another specific position (e.g. the fixing hole 211 is aligned with the location hole 902), the rotation portion 22 and the spring 221 are turned to the first position, so that the connecting portion 222 passes through the fixing hole 211 of the stationary portion 21 and the location hole 901 of the functional apparatus 9 for connecting to the stationary portion 21 and the functional apparatus 9. Thus, the functional apparatus 9 can not be rotated.

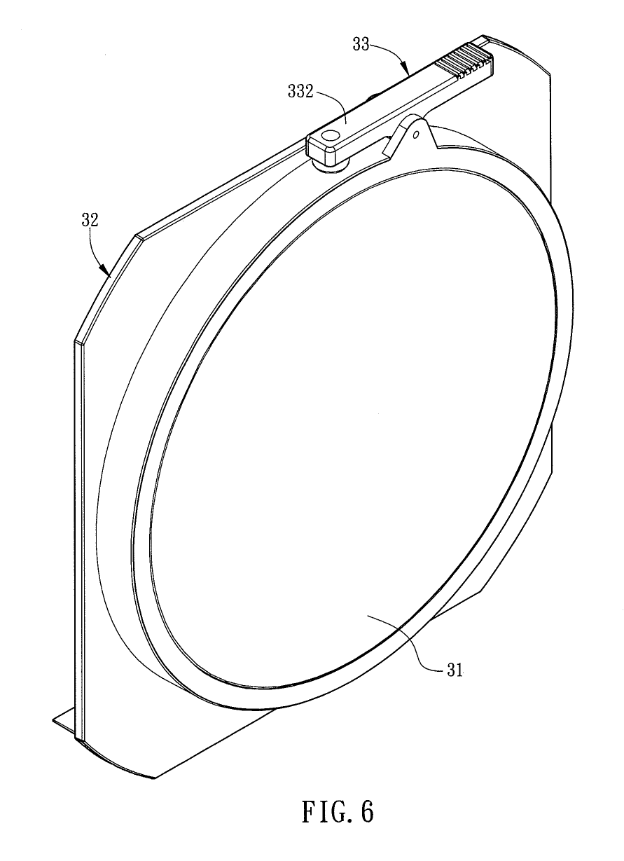

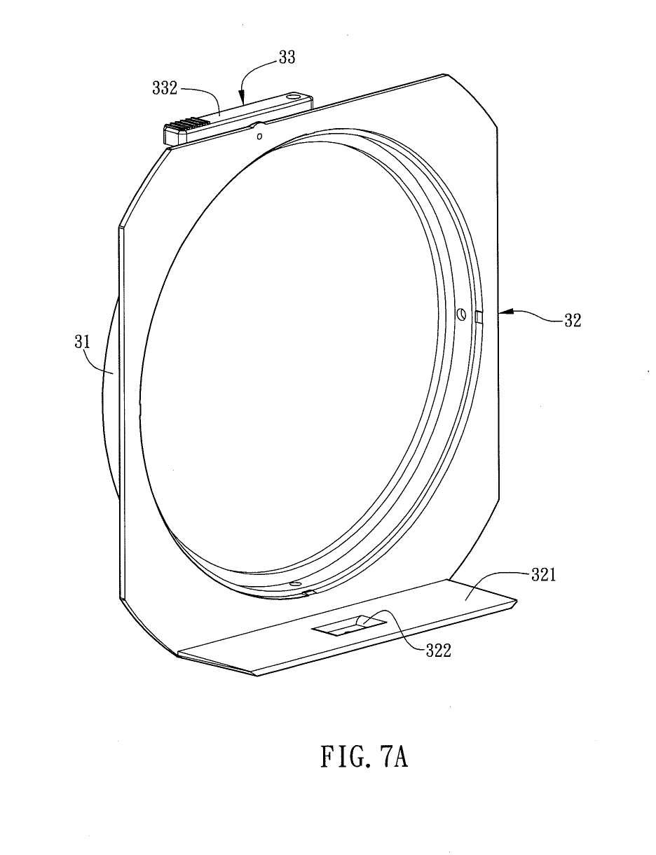

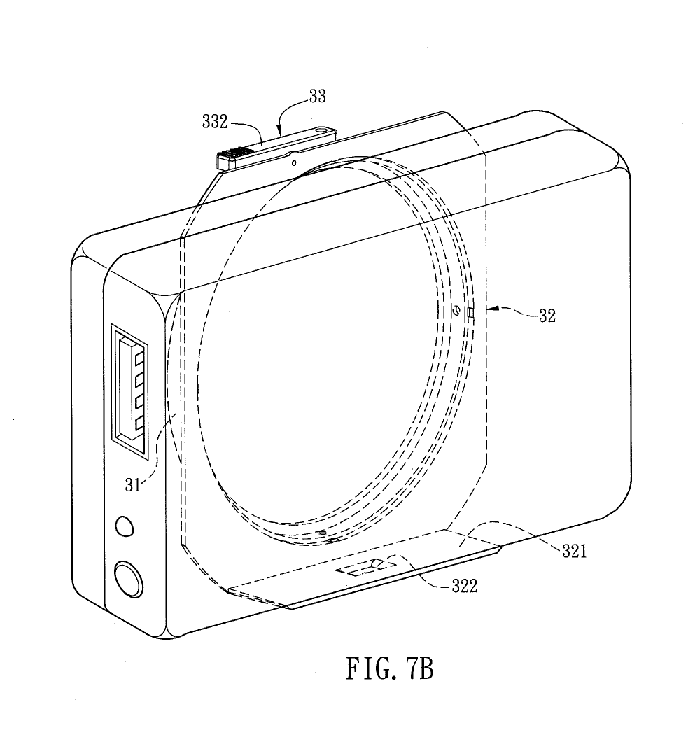

FIGS. 6 and 7A are schematic diagrams of a stationary portion 31 and a rotation portion 32 of an electronic apparatus with rotation function according a third embodiment of the disclosure in different view, and FIG. 7B is a schematic diagram of the functional apparatus 9 connecting with the rotation portion 32 according the third embodiment.

Referring to FIGS. 6 to 7B, the stationary portion 31 is integrally formed at the loading side of the electronic apparatus and forms a solid circle. The rotation portion 32 may include a circle part, a sector part, a ring part, or an arc part for connecting with the stationary portion 31 in an unfixed way. In this embodiment, the rotation portion 32 includes a ring part for example. The inner periphery of the ring part and the outer periphery of the stationary portion 31 are connected, so that the rotation portion 32 can rotate with respect to the stationary portion 31.

In addition, the electronic apparatus further comprises a limiting unit 33, which connects with the stationary portion 31 or the rotation portion 32. The limiting unit 33 includes a first position and a second position. In this embodiment, the limiting unit 33 connects with the rotation portion 32. When the limiting unit 33 is in the first position, it can relatively fix the stationary portion 31 with the rotation portion 32; otherwise, when the limiting unit 33 is in the second position, the rotation portion 32 is rotatable with respect to the stationary portion 31.

In this embodiment, the limiting unit 33 includes a spring (not shown), a connecting portion 332 and a bolt (not shown). The elements of the limiting unit 33 and their operations are the same as those of the rotation portion 12 of the first embodiment, so the detailed descriptions thereof will be omitted. In brief, when the limiting unit 33 and the spring are in the first position, the connecting portion 332 locks the stationary portion 31 with the rotation portion 32, so that the rotation portion 32 as well as the functional apparatus (not shown) fixed thereon can not rotate with respect to the stationary portion 31.

When the limiting unit 33 and the spring are in the second position, the connecting portion 332 separates from the stationary portion 31, so that the rotation portion 32 as well as the functional apparatus fixed thereon can rotate with respect to the stationary portion 31. After the rotation portion 32 and the functional apparatus fixed thereon are rotated to a specific position, the limiting unit 33 and the spring are turned to the first position, so that the rotation portion 32 as well as the functional apparatus fixed thereon can be fixed at this specific position.

In addition, as shown in FIGS. 7A and 7B, the rotation portion 32 further comprises a stage 321 for fixing the functional apparatus. The stage 321 includes a recess 322 for installing the function apparatus.

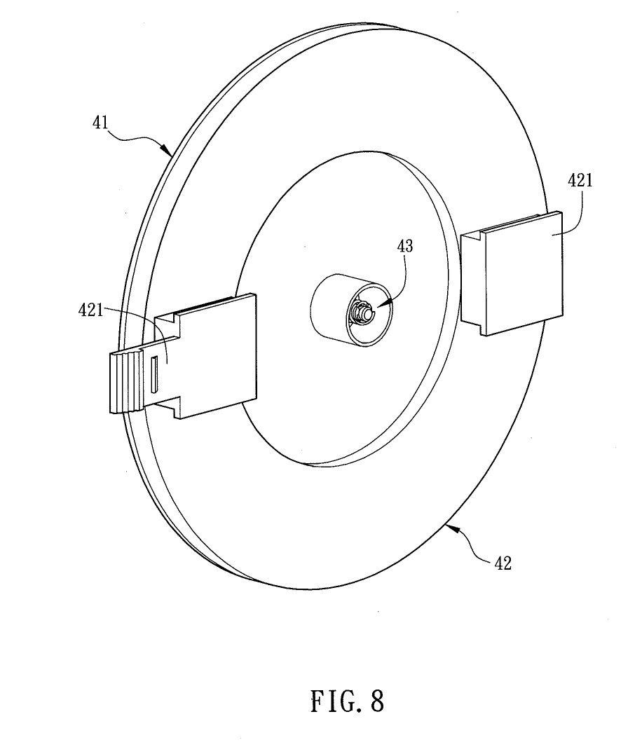

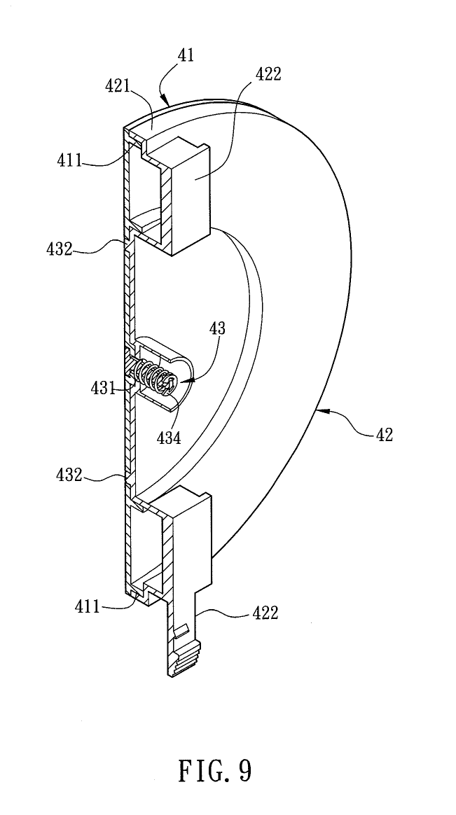

FIG. 8 is an assembled diagram of a stationary portion 41 and a rotation portion 42 of an electronic apparatus with rotation function according to a fourth embodiment of the disclosure, and FIG. 9 is a sectional view of the stationary portion 41 and the rotation portion 42 of FIG. 8.

Referring to FIGS. 8 and 9, the stationary portion 41 is integrally formed at the loading side of the electronic apparatus. The rotation portion 42 is connected with the stationary portion 41 in an unfixed way, so that the rotation portion 42 and the functional apparatus (not shown) disposed thereon can rotate relative to the stationary portion 41. In this embodiment, the stationary portion 41 includes a protrusion ring 411, and the rotation portion 42 includes a ring portion 421. The ring portion 421 is connected with the protrusion ring 411, such that the rotation portion 42 can rotate with respect to the stationary portion 41.

The electronic apparatus further comprises a limiting unit 43, which connects with the stationary portion 41 and the rotation portion 42. The limiting unit 43 includes a first position and a second position. When the limiting unit 43 is in the first position, it can fix the stationary portion 41 and the rotation portion 42; otherwise, when the limiting unit 43 is in the second position, the rotation portion 42 is rotatable with respect to the stationary portion 41.

The limiting unit 43 can achieve the positioning function by a spring 431, a connecting portion 432, and a fixing ring 434, which are similar to the structure of the rotation portion 22 of the second embodiment, so the detailed descriptions thereof will be omitted.

In order to rotate the rotation portion 42 with respect to the stationary portion 41, a supporting portion 422 is pull up to separate the connecting portion 432 from the rotation portion 42. Accordingly, the rotation portion 42 can rotate with respect to the stationary portion 41. In this circumstance, the limiting unit 43 and the spring 431 are in the second position. After the rotation portion 42 includes rotated to a specific position, the supporting portion 422 is released, so that the limiting unit 43 can lock the stationary portion 41 and the rotation portion 42. In this circumstance, the limiting unit 43 and the spring 431 are in the first position (see FIG. 9).

In addition, the supporting portion 422 of the rotation portion 42 allows the functional apparatus to be fastened on the rotation portion 42 by hanging.

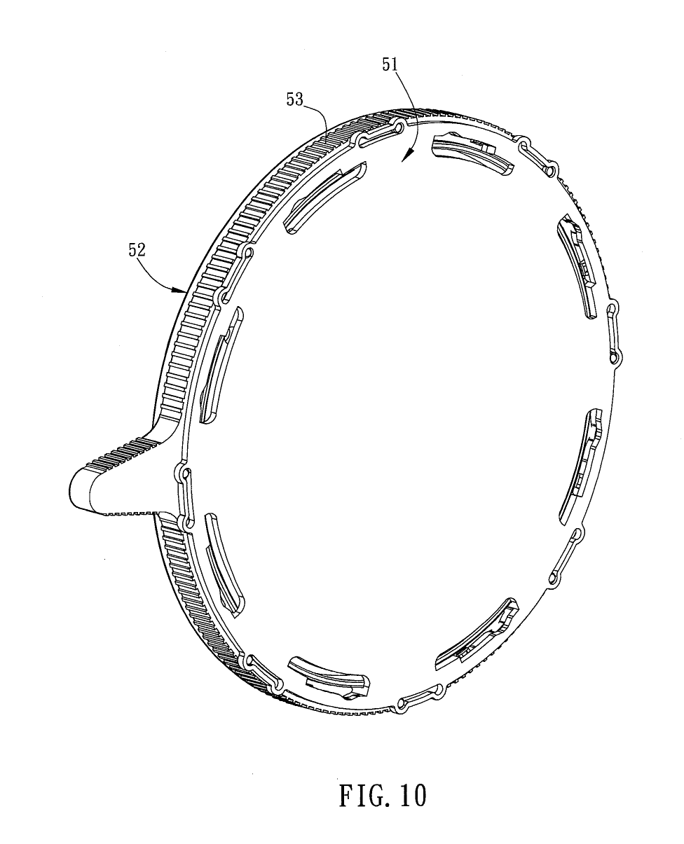

FIG. 10 is an assembled diagram of a stationary portion 42 and a rotation portion 52 of an electronic apparatus with rotation function according to a fifth embodiment of the disclosure. The stationary portion 51 is integrally formed at the loading side of the electronic apparatus. The rotation portion 52 is connected with the stationary portion 51 in an unfixed way, so that the rotation portion 52 and the functional apparatus (not shown) disposed thereon can rotate relative to the stationary portion 51.

The electronic apparatus further comprises a limiting unit 53, which connects with the stationary portion 51 or the rotation portion 52. The limiting unit 53 includes a first position and a second position. When the limiting unit 53 is in the first position, it can fix the stationary portion 51 and the rotation portion 52; otherwise, when the limiting unit 53 is in the second position, the rotation portion 52 is rotatable with respect to the stationary portion 51. In brief, when the limiting unit 53 is in the second position, the rotation portion 52 is capable of rotating with respect to the stationary portion 51. In contrary, when the limiting unit 53 is in the first position, the rotation portion 52 is fixed. In this embodiment, the limiting unit 53 comprises a gear for example.

In summary, the electronic apparatus of this disclosure includes a stationary portion and a rotation portion, which are disposed on the loading side thereof, and the rotation portion is capable of rotating with respect to the stationary portion and connecting to a functional apparatus (e.g. a small sized host). Thus, the functional apparatus can be rotated with respect to the stationary portion by the rotation portion, so that the functional apparatus can be rotated to a proper position for the user to conveniently insert the connecters or operate the operation interface. Besides, the stationary portion can be integrally formed on the electronic apparatus, so the conventional frame is not needed anymore. Therefore, the user does not have to install the frame, and can avoid the inconvenient problems of inserting the connecters. Accordingly, the usage performance can be sufficiently enhanced.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. An electronic apparatus with rotation function, comprising:
a loading side;
a stationary portion disposed at the loading side; and
a rotation portion configured for connecting with a functional apparatus, wherein the functional apparatus rotates relative to the stationary portion by the rotation portion.

2. The electronic apparatus of claim 1, further comprising:
a limiting unit connecting to the stationary portion or the rotation portion and having a first position and a second position, wherein when located at the first position, the limiting unit relatively restricts the movement of the stationary portion and the rotation portion, and when located at the second position, the rotation portion is rotated relatively with the stationary portion.

3. The electronic apparatus of claim 2, wherein the limiting unit comprises a spring and a connection portion, the connection portion is connected with the stationary portion and the rotation portion when the spring is in the first position, and the connection portion is separated from the stationary portion or the rotation portion when the spring is in the second position.

4. The electronic apparatus of claim 3, wherein the connection portion is a protrusion rod or a protrusion base.

5. The electronic apparatus of claim 3, wherein the connection portion has a recess, and a fixing ring is disposed in the recess for restricting the spring.

6. The electronic apparatus of claim 3, wherein the limiting unit further comprises a bolt for passing through the connection portion and the stationary portion.

7. The electronic apparatus of claim 1, wherein the stationary portion is disposed at the loading side by hooking, telescoping, locking or integrally forming.

8. The electronic apparatus of claim 1, wherein the electronic apparatus is a television, a display, or a computer.

9. The electronic apparatus of claim 1, wherein the functional apparatus is a computer host, an optical disc drive, a server, a printer, a router, a wireless access point, or a processor.

10. The electronic apparatus of claim 1, wherein the functional apparatus further comprises a plurality of connecting ports.
